(19) United States
(12) Patent Application Publication
(10) Pub. No.: US 2010/0081236 A1
(43) Pub. Date: Apr. 1, 2010

(54) METHOD OF MANUFACTURING SEMICONDUCTOR DEVICE WITH EMBEDDED INTERPOSER

(75) Inventors: Se-Young Yang, Seongnam-si (KR); Kyu-Jin Lee, Cheonan-si (KR); Pyoung-Wan Kim, Suwon-si (KR); Keum-Hee Ma, Suwon-si (KR); Chul-Yong Jang, Yongin-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd, Suwon-si (KR)

(21) Appl. No.: 12/570,047

(22) Filed: Sep. 30, 2009

(30) Foreign Application Priority Data
Oct. 1, 2008 (KR) 2008-96558

(51) Int. Cl. H01L 21/60

(52) U.S. Cl. 438/119; 438/121; 257/E21.511

(57) ABSTRACT

A method of manufacturing a semiconductor device includes forming printed circuit board (PCB) having an embedded interposer. A semiconductor chip or a semiconductor package is mounted onto the embedded interposer using a conductive adhesive agent. The embedded interposer has substantially the same coefficient of thermal expansion (CTE) as the semiconductor chip. The embedded interposer is formed using a semiconductor wafer.

### CROSS-REFERENCE TO RELATED APPLICATIONS

This application claims priority under 35 U.S.C. §119 from Korean Patent Application No. 10-2008-0096558, filed on Oct. 1, 2008, the contents of which are hereby incorporated herein by reference in its entirety.

### BACKGROUND

1. Field of the General Inventive Concept

Example embodiments relate to a method of forming a semiconductor device, and more particularly, to a method of manufacturing a semiconductor device with an embedded interposer.

2. Description of the Related Art

As semiconductor devices are becoming ever smaller, techniques to mount semiconductor chips onto a printed circuit board (PCB) are being actively researched. A semiconductor chip may be provided in a form of a direct chip attach (DCA) package such as a wafer level package (WLP) or a flip chip package. The DCA package is electrically connected to the PCB.

Generally, semiconductor substrates and PCBs have different coefficients of thermal expansion (CTEs). Because of CTE mismatch between the semiconductor substrate and the PCB, if a semiconductor device is exposed to temperature variation, a defect such as a solder joint crack may occur. The solder joint crack increases electrical resistance and decreases mechanical bond strength between the semiconductor substrate and the PCB.

For example, a semiconductor device may be repeatedly exposed to temperature increases/decreases due to its own operation and/or the surrounding environment. In this case, different thermal expansion of the semiconductor substrate and the PCB can result in different displacement and shear strain on a solder ball connected between the semiconductor substrate and the PCB. Such shear strain causes the solder joint to crack.

Another semiconductor package technique is disclosed in Korean Patent Publication No. 10-2003-0069774 to Yoneda Yoshiyuki et al., entitled “SUBSTRATE FOR SEMICONDUCTOR DEVICE, METHOD OF MANUFACTURING THE SAME AND SEMICONDUCTOR PACKAGE.”

### SUMMARY

Example embodiments of the present general inventive concept provide a method of manufacturing a semiconductor device in which solder joint reliability is improved.

Additional aspects and utilities of the present general inventive concept will be set forth in part in the description which follows and, in part, will be obvious from the description, or may be learned by practice of the general inventive concept.

Embodiments of the present general inventive concept may be achieved by providing a printed circuit board (PCB) having an embedded interposer. A semiconductor chip or a semiconductor package is mounted onto the embedded interposer using a conductive adhesive agent. The embedded interposer has substantially the same coefficient of thermal expansion (CTE) as the semiconductor chip.

The embedded interposer may be formed using a semiconductor wafer.

The PCB may be formed by preparing a base substrate, and attaching the embedded interposer to the base substrate. The method may further include forming a photo solder resist (PSR) layer which covers the embedded interposer.

The method may further include forming a lamination layer which covers the base substrate. The lamination layer may have a cavity which partially exposes the base substrate, and the embedded interposer may be disposed in the cavity.

The method may further include forming a cavity in the base substrate. The embedded interposer may be disposed in the cavity.

The method may further include forming a redistribution layer which electrically connects the embedded interposer to the base substrate. The redistribution layer may be formed using an ink jet technique.

The method may further include forming a through silicon via (TSV) which penetrates the embedded interposer.

The conductive adhesive agent may include one selected from the group consisting of a solder ball, a solder paste, a conductive bump, an anisotropic conductive film (ACF), and an anisotropic conductive paste (ACP).

The semiconductor package may include one selected from the group consisting of a wafer level chip scale package (WL CSP), a flip chip package, and a multi-chip package (MCP).

Embodiments of the present general inventive concept may also be achieved by forming a printed circuit board (PCB) which includes an embedded interposer and a plurality of tabs. A semiconductor chip or a semiconductor package is mounted onto the embedded interposer using a conductive adhesive agent. The embedded interposer has substantially the same coefficient of thermal expansion (CTE) as the semiconductor chip, and the tabs are electrically connected to the semiconductor chip or the semiconductor package.

The semiconductor package may include one selected from the group consisting of a wafer level chip scale package (WL CSP), a flip chip package, and a multi-chip package (MCP). The semiconductor package may include a dynamic random access memory (DRAM).

Embodiments of the present general inventive concept may also be achieved by forming a printed circuit board (PCB) which includes an embedded interposer and card terminals. A semiconductor chip or a semiconductor package is mounted onto the embedded interposer using a conductive adhesive agent. The embedded interposer has substantially the same coefficient of thermal expansion (CTE) as the semiconductor chip, and the card terminals are electrically connected to the semiconductor chip or the semiconductor package.

The semiconductor package may include one selected from the group consisting of a wafer level chip scale package (WL CSP), a flip chip package, and a multi-chip package (MCP). The semiconductor package may include a non-volatile memory device.

Embodiments of the present general inventive concept may also be achieved by providing a substrate having a plurality of interconnections disposed therein and forming a printed circuit board (PCB), a photo resist solder (PSR) layer formed above the PCB, an embedded interposer partially embedded in the PCB and partially embedded in the PSR layer, the embedded interposer having a coefficient of thermal expansion (CTE), a semiconductor chip formed above the PCB, the semiconductor chip having substantially the same CTE as the embedded interposer, and a conductive adhesive agent formed between the embedded interposer and the semiconductor chip.

The embedded interposer may be formed at the same horizontal level as a plurality of redistribution layers.

Embodiments of the present general inventive concept may also be achieved by providing a first semiconductor substrate having a first level and a second level, the first level having a plurality of interconnections therein and the second level having a cavity formed therein, an embedded interposer disposed within the cavity, the embedded interposer formed of a semiconductor material having a coefficient of thermal expansion (CTE), a plurality of metal connection layers disposed above the embedded interposer, at least one conductive adhesive agent disposed above the embedded interposer and separately formed with respect to the metal interconnection layers, a second semiconductor substrate disposed above the plurality of metal connection layers, a semiconductor chip disposed above the second substrate and having a CTE substantially the same as the embedded interposer, and a conductive layer electrically connecting the second substrate and the semiconductor chip.

A photoresist layer may be formed above the first semiconductor substrate, one of the plurality of metal connection layers, and the embedded interposer, wherein the conductive adhesive layer may be partially embedded in the photoresist layer.

Embodiments of the present general inventive concept may also be achieved by forming a semiconductor substrate having a plurality of first interconnects therein and a plurality of second interconnects disposed above the semiconductor substrate, forming a lamination layer above the semiconductor substrate and above the plurality of second interconnects, the lamination layer being formed with a cavity therein, embedding an interposer having a coefficient of thermal expansion (CTE) in the cavity of the lamination layer through an adhesive agent, forming through silicon vias (TSVs) in the embedded interposer to contact the first interconnects, forming a conductive adhesive layer and a plurality of metal interconnects above the TSVs, forming a plurality of semiconductor chips above the plurality of metal interconnects, wherein the plurality of semiconductor chips have substantially the same CTE as the embedded interposer.

A packaging substrate may also be formed between the conductive adhesive layer and below the plurality of semiconductor chips.

### BRIEF DESCRIPTION OF THE DRAWINGS

Example embodiments are described in further detail below with reference to the accompanying drawings. It should be understood that various aspects of the drawings may have been exaggerated for clarity.

These and/or other features and utilities of the present general inventive concept will become apparent and more readily appreciated from the following description of the embodiments, taken in conjunction with the accompanying drawings of which:

FIGS. 1 to 5 are cross-sectional views illustrating a method of manufacturing a semiconductor device according to an example embodiment;

FIGS. 6 to 9 are cross-sectional views illustrating a method of manufacturing a semiconductor device according to another example embodiment;

FIGS. 10 to 13 are cross-sectional views illustrating a method of manufacturing a semiconductor device according to yet another example embodiment;

FIGS. 14 to 18 are cross-sectional views illustrating a method of manufacturing a semiconductor device according to still another example embodiment;

FIGS. 19 to 21 are cross-sectional views illustrating a method of manufacturing a semiconductor device according to still another example embodiment;

FIG. 22 is a cross-sectional view illustrating a method of manufacturing a semiconductor device according to still another example embodiment;

FIG. 23 is a plan view illustrating a method of manufacturing a semiconductor device according to still another example embodiment;

FIG. 24 illustrates a cross-sectional view taken along line I-I′ of FIG. 23;

FIG. 25 is a plan view illustrating a method of manufacturing a semiconductor device according to yet another example embodiment;

FIG. 26 illustrates an exploded cross-sectional view taken along line II-II′ of FIG. 25; and

FIG. 27 illustrates a cross-sectional view taken along line II-II′ of FIG. 25.

### DETAILED DESCRIPTION OF THE EMBODIMENTS

Various example embodiments will now be described more fully with reference to the accompanying drawings in which some example embodiments are illustrated, wherein like reference numerals refer to the like elements throughout. The embodiments are described below in order to explain the present general inventive concept by referring to the figures. In the drawings, the thicknesses of layers and regions may be exaggerated for clarity.

Detailed illustrative embodiments are disclosed herein. However, specific structural and functional details disclosed herein are merely representative for purposes of describing example embodiments. This present general inventive concept, however, may be embodied in many alternate forms and should not be construed as limited to only example embodiments set forth herein.

Accordingly, while example embodiments are capable of various modifications and alternative forms, embodiments thereof are illustrated by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the present general inventive concept. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof. Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation which is above as well as below. For example, a term “filling layer” can be used to describe an “under-fill” in a semiconductor packaging line, and a term “side pillar” can be used to describe a “side fill” which aids a filling layer in a semiconductor packaging line. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures illustrated in succession may in fact be executed substantially concurrently or may sometimes be executed in the reverse order, depending upon the functionality/acts involved.

In order to more specifically describe example embodiments, various aspects will be described in detail with reference to the attached drawings. However, the present general inventive concept is not limited to example embodiments described.

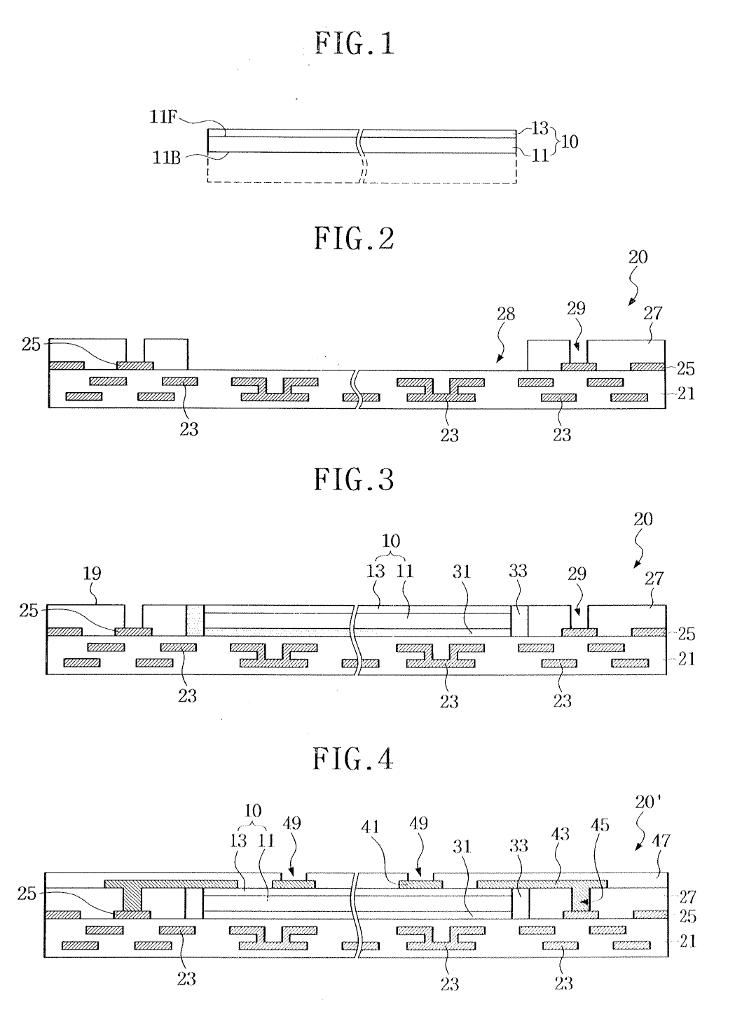

FIGS. 1 to 5 are cross-sectional views illustrating a method of manufacturing a semiconductor device according to an example embodiment.

Referring to FIG. 1, an embedded interposer 10 which includes an interposer substrate 11 and a first insulating layer 13 may be formed. The interposer substrate 11 may have a front surface 11F and a back surface 11B which opposes the front surface 11F. The first insulating layer 13 may be formed to cover the front surface 11F.

In detail, the interposer substrate 11 may be formed using a semiconductor wafer such as a bulk silicon (Si) wafer. The bulk silicon wafer with may have a thickness of at least 1 mm. In this case, the interposer substrate 11 may be formed to a thickness of 0.05 mm to 0.3 mm by polishing the bulk silicon wafer. The bulk silicon wafer may be polished using a chemical mechanical polishing (CMP) technique and/or an etch-back technique.

The various dimensions of the embedded interposer 10 including the length, width, and depth may help to improve solder joint reliability of a semiconductor package. As described and illustrated herein, the thicker the depth of an embedded interposer, the more a solder joint reliability may be improved for solder, metal layers and interconnections formed between a PCB and a semiconductor chip or package.

The first insulating layer 13 may be formed of a silicon oxide layer, a silicon nitride layer, a silicon oxy-nitride layer, or a combination thereof. The first insulating layer 13 may be formed using a chemical vapor deposition (CVD) technique, a thermal oxidation technique, or a spin coating technique. The first insulating layer 13 may be formed before or after the process to polish the bulk silicon wafer. Conductive interconnections (not illustrated) may be formed on the first insulating layer 13, but for simplicity they are not illustrated in the drawing. The first insulating layer 13 may be formed to a thickness less than the interposer substrate 11.

Referring to FIG. 2, a preliminary PCB 20 may be formed by stacking a lamination layer 27 on a base substrate 21. The preliminary PCB 20 may be formed to have a cavity 28 which is defined by the lamination layer 27.

In detail, the base substrate 21 may be formed of a flexible PCB and/or a rigid PCB. The base substrate 21 may be formed of a multi-layer PCB which has first interconnections 23 and second interconnections 25. The first interconnections 23 may be formed inside the base substrate 21. The second interconnections 25 may be formed on a surface of the base substrate 21. The first interconnections 23 and the second interconnections 25 may be formed of a conductive layer which is made of Cu, W, WN, Ti, TiN, Ta, TaN, Au, Ag, Ni, Pt, or a combination thereof.

The lamination layer 27 may be formed to cover the base substrate 21. The lamination layer 27 may be formed to have the cavity 28 which partially exposes a surface of the base substrate 21 and a contact hole 29 which exposes the second interconnections 25. The lamination layer 27 may be formed of an insulating material layer. When the lamination layer 27 is formed to cover the base substrate 21, the combined structure may form a PCB in which an interposer 10 may be embedded in the cavity 28.

Referring to FIG. 3, the embedded interposer 10 may be attached to a portion of the base substrate 21 which is exposed by the cavity 28 using an adhesive agent 31. The adhesive agent 31 may be formed between the base substrate 21 and the back surface 11B. A spacer 33 may be formed between the lamination layer 27 and the embedded interposer 10. The spacer 33 may be formed of an insulating material layer. The spacer 33 may be formed of the same material layer as the adhesive agent. An upper surface of the embedded interposer 10 may be at substantially the same level as an upper surface of the lamination layer 27.

Referring to FIG. 4, redistribution layers 41, 43 and 45 and a photo solder resist (PSR) layer 47 may be formed on the lamination layer 27 and the embedded interposer 10. The base substrate 21, the lamination layer 27, the embedded interposer 10, the redistribution layers 41, 43 and 45, and the PSR layer 47 may configure a PCB 20′.

The redistribution layers 41, 42 and 45 may include external connection terminals 41, contact plugs 45 and third interconnections 43. The external connection terminals 41 may be formed on the first insulating layer 13, the third interconnections 43 may be formed to cross or cover both of the first insulating layer 13 and the lamination layer 27, and the contact plugs 45 may be formed to fill the contact hole 29. That is, the contact plugs 45 may be in contact with the third interconnections 43 and the second interconnections 25. The redistribution layers 41, 43 and 45 may be formed of a conductive layer which is made of Cu, W, WN, Ti, TiN, Ta, TaN, Au, Ag, Ni, Pt, or a combination thereof. The redistribution layers 41, 43 and 45 may be formed of a conductive paste such as a solder paste or a conductive tape. For example, the redistribution layers 41, 43 and 45 may be formed using an ink jet technique.

The PSR layer 47 may be formed to cover the lamination layer 27, the embedded interposer 10 and the redistribution layers 41, 43 and 45. The PSR layer 47 may be formed to have openings 49 which expose the external connection terminals 41. The PSR layer 47 may be formed of an insulating material layer. Alternatively, the embedded interposer 10 may be formed to be partially embedded in the PCB 20′ with a portion of the embedded interposer 10 being disposed or overlapped above a top surface 19 (as illustrated in FIGS. 16-17) of the preliminary PCBs 20 and 20′ to be also partially embedded in the PSR layer 47

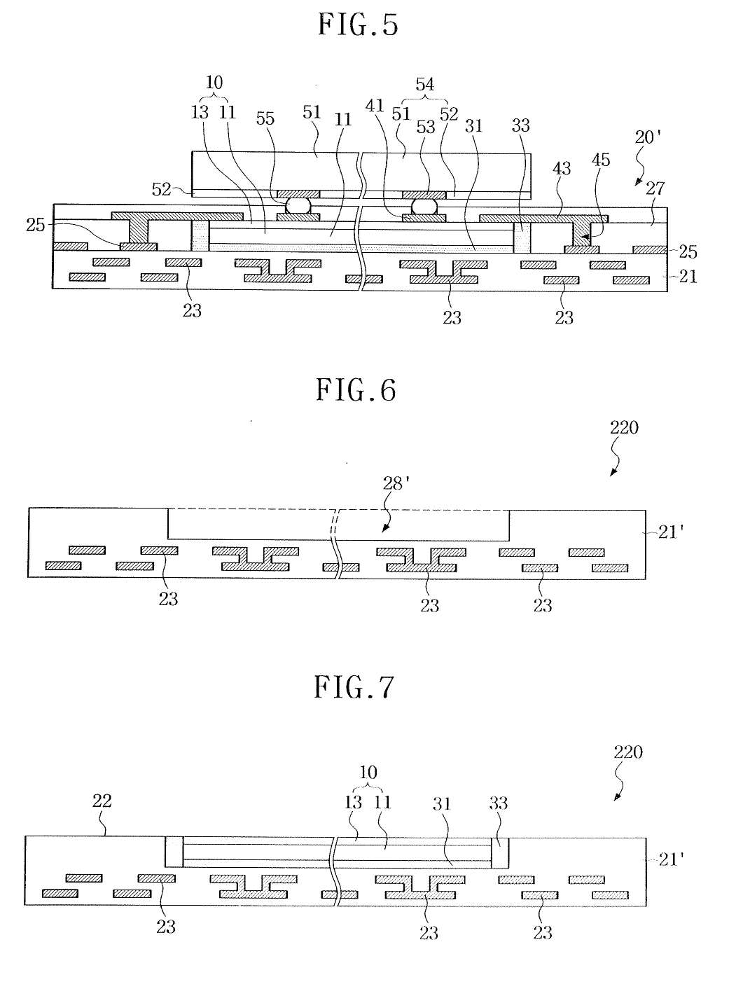

Referring to FIG. 5, a Wafer Level Chip Scale Package (WL CSP) 54 may be mounted on the PCB 20′.

The WL CSP 54 may be formed to have a semiconductor chip 51, a wafer redistribution layer 52 and package terminals 53. The semiconductor chip 51 may be formed using a semiconductor wafer such as a silicon wafer. The wafer redistribution layer 52 may be formed to cover the semiconductor chip 51. The package terminals 53 may be exposed outside a surface of the wafer redistribution layer 52. The package terminals 53 may be formed of a conductive layer which is made of Cu, W, WN, Ti, TiN, Ta, TaN, Au, Ag, Ni, Pt, or a combination thereof.

The WL CSP 54 may be attached to the embedded interposer 10 using a solder joint such as a conductive adhesive agent 55. The conductive adhesive agent 55 may be disposed between the package terminals 53 and corresponding ones of the external connection terminals 41. The conductive adhesive agent 55 may be one selected from the group consisting of a solder ball, a solder paste, a conductive bump, an anisotropic conductive film (ACF), and an anisotropic conductive paste (ACP). The conductive adhesive agent 55 may serve to mechanically/electrically connect the semiconductor chip 51 to the PCB 20′.

The embedded interposer 10 may be formed to have substantially the same CTE as the semiconductor chip 51. For example, the interposer substrate 11 and the semiconductor chip 51 may be formed using a semiconductor wafer. Accordingly, mechanical/electrical characteristics of the conductive adhesive agent 55 disposed between a PCB and semiconductor chip may be significantly improved compared to the conventional art.

As illustrated in FIG. 5, the embedded interposer 10 may be embedded within the PCB 20′ such that the semiconductor layer 11 of the embedded interposer 10 is formed at the same level as redistribution layer 45 and beneath redistribution layers 41 and 43, which are positioned above the embedded interposer 10. Because of the positioning of the redistribution layers 41 and 43, the conductive adhesive agent 55, and the wafer distribution layer 53 between the PCB 21 and the embedded interposer 10, the strength, durability and electrical conductivity of the solder joint that includes these layers may be improved as a result of the CTE matching between the semiconductor chip and the embedded interposer 10.

As another example embodiment, the WL CSP 54 may be replaced with a different semiconductor chip (not illustrated). For example, the different semiconductor chip can have a similar configuration to one in which the wafer redistribution layer 52 is not formed. In this case, the different semiconductor chip may be attached to the embedded interposer 10 using the conductive adhesive agent 55.

As still another example embodiment, the WL CSP 54 may be replaced with a different semiconductor package such as a flip chip package and/or a multi-chip package (MCP).

In addition, the semiconductor chips described in the above example embodiments may include a volatile memory device such as a dynamic random access memory (DRAM), a non-volatile memory device such as a flash memory, a microprocessor, a logic device, or a combination thereof.

FIGS. 6 to 9 are cross-sectional views illustrating a method of manufacturing a semiconductor device according to another example embodiment. The present example embodiment will be described below by focusing on differences with respect to the previous example embodiment.

Referring to FIG. 6, a cavity 28′ may be formed in a base substrate 21′. The base substrate 21′ may include first interconnections 23. The base substrate 21′ may configure a preliminary PCB 220.

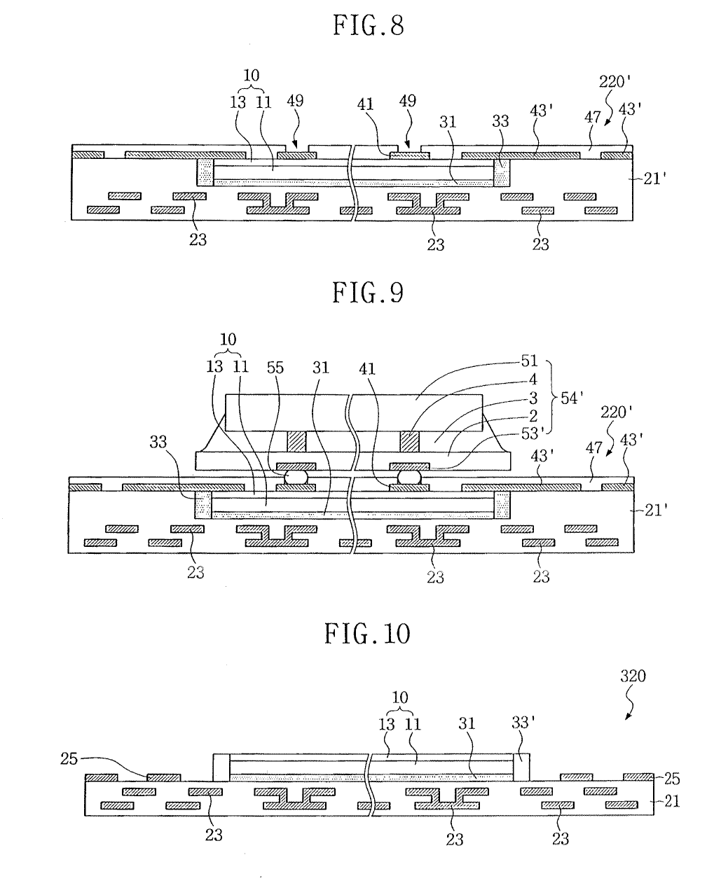

Referring to FIG. 7, an embedded interposer 10 may be attached to the base substrate 21′ using an adhesive agent 31. The embedded interposer 10 may be disposed in the cavity 28′. The adhesive agent 31 may be disposed between the base substrate 21′ and an interposer substrate 11. A spacer 33 may be formed on a sidewall of the embedded interposer 10. The spacer 33 may be formed to fill a space between the embedded interposer 10 and the base substrate 21′. A surface of the embedded interposer 10 may be at substantially the same level as a surface of the base substrate 21′. Alternatively, the embedded interposer 10 may be formed to be partially embedded in the base substrate 21′ with a portion of the embedded interposer 10 disposed above and overlapping a top surface 22 (as illustrated in FIGS. 16-17) of the base substrate 21′ to be also partially embedded in a PSR layer 47 (illustrated in FIG. 8).

Referring to FIG. 8, redistribution layers 41 and 43′ and a PSR layer 47 may be formed on the base substrate 21′ and the embedded interposer 10. The base substrate 21′, the embedded interposer 10, the redistribution layers 41 and 43′, and the PSR layer 47 may configure a PCB 220′.

The redistribution layers 41 and 43′ may include external connection terminals 41 and third interconnections 43′. The external connection terminals 41 may be formed on a first insulating layer 13, and the third interconnections 43′ may be formed to cross the first insulating layer 13 and the base substrate 21′. The PSR layer 47 may be formed to cover the base substrate 21′, the embedded interposer 10, and the redistribution layers 41 and 43′. The PSR layer 47 may be formed to have openings 49 which expose the external connection terminals 41.

As illustrated in FIG. 8, the position of the embedded interposer of the present embodiment may be characterized in that the embedded interposer 10 is not positioned adjacent, in a horizontal direction, to any of the first interconnections 23, or the distribution layers 41 or 43′. The substrate 21′ may have a first level including a plurality of interconnects and a second level free of interconnects that defines a cavity 28′ (illustrated in FIG. 6). Thus, the embedded interposer 10 is not positioned at the same level as any redistribution layer. A benefit of this configuration may be that when forming a thicker embedded interposer 10, a thickness of an upper portion of the base substrate 21′ that is free of interconnects may be increased to match the thickness of the interposer without regard to interconnection layers included therein. A thicker embedded interposer 10 having more depth in the substrate 21′ may increase the strength of the solder joints between the semiconductor chip 51 and embedded interposer 10 as a result of the CTE matching between the chip and the interposer, as later illustrated in Table 1.

Referring to FIG. 9, a flip chip package 54′ may be mounted on the PCB 220′.

The flip chip package 54′ may be formed to have a semiconductor chip 51, a package substrate 2, an underfill 3, package inner interconnections 4, and package terminals 53′. The semiconductor chip 51 may be formed using a semiconductor wafer such as a silicon wafer. The embedded interposer 10 may be formed to have substantially the same CTE as the semiconductor chip 51. The underfill 3 may be formed between the semiconductor chip 51 and the package substrate 2. The package inner interconnections 4 may be formed to penetrate the underfill 3 between the semiconductor chip 51 and the package substrate 2. The package interconnections 4 may be one selected from the group consisting of a solder ball, a solder paste, a conductive bump, an anisotropic conductive film (ACF), and an anisotropic conductive paste (ACP). The package interconnections 4 may serve to provide an electrical connection path between the semiconductor chip 51 and the package substrate 2. The package terminals 53′ may be exposed outside a surface of the package substrate 2. The package terminals 53′ may be electrically connected to the semiconductor chip 51 via the package inner interconnections 4.

The flip chip package 54′ may be attached to the embedded interposer 10 using a solder joint such as a conductive adhesive agent 55. The conductive adhesive agent 55 may be disposed between the package terminals 53′ and the external connection terminals 41. The conductive adhesive agent 55 may be one selected from the group consisting of a solder ball, a solder paste, a conductive bump, an anisotropic conductive film (ACF), and an anisotropic conductive paste (ACP). The conductive adhesive agent 55 may serve to mechanically/electrically connect the semiconductor chip 51 to the PCB 220′.

As yet another example embodiment, the flip chip package 54′ may be replaced with a different semiconductor package such as a WL CSP or an MCP.

FIGS. 10 to 13 are cross-sectional views illustrating a method of manufacturing a semiconductor device according to another example embodiment.

Referring to FIG. 10, an embedded interposer 10 may be attached to a base substrate 21 using an adhesive agent 31. A multi-layer PCB which includes first interconnections 23 and second interconnections 25 may be used as the base substrate 21. The base substrate 21 may configure a preliminary PCB 320. Spacers 33′ may be formed on sidewalls of the embedded interposer 10. The spacer 33′ may be formed of an insulating material layer. The embedded interposer 10 may protrude from the base substrate 21.

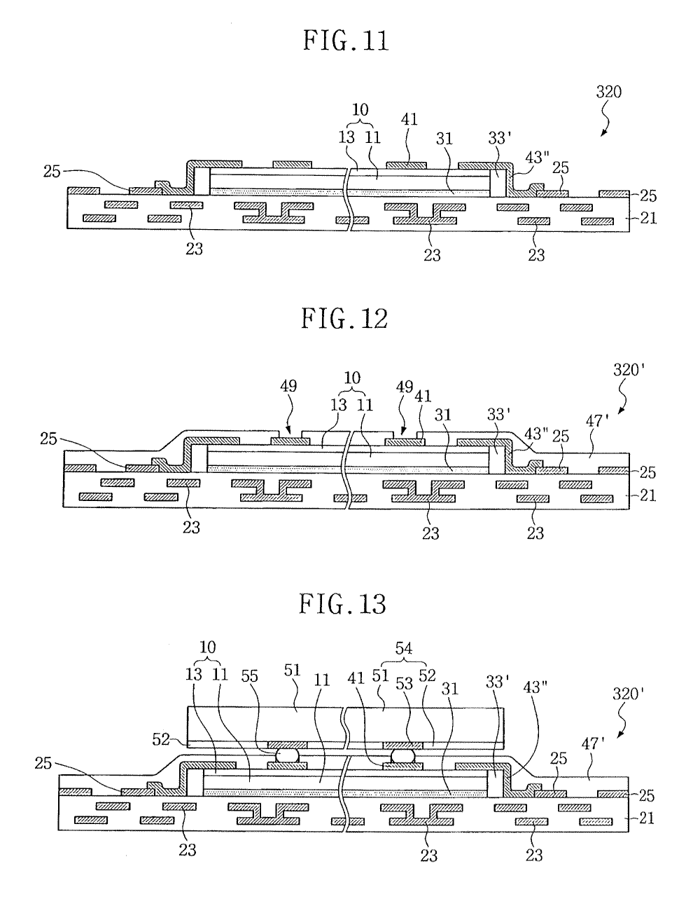

Referring to FIG. 11, redistribution layers 41 and 43″ may be formed on the base substrate 21 and the embedded interposer 10.

The redistribution layers 41 and 43″ may include external connection terminals 41 and third interconnections 43″. The external connection terminals 41 may be formed on a first insulating layer 13, and the third interconnections 43″ may be formed to cross the first insulating layer 13, the spacer 33′ and the base substrate 21. The third interconnections 43″ may contact second interconnections 25. The redistribution layers 41 and 43″ may be formed of a conductive layer which is made of Cu, W, WN, Ti, TiN, Ta, TaN, Au, Ag, Ni, Pt, or a combination thereof. The redistribution layers 41 and 43″ may be formed of a conductive paste such as a solder paste or a conductive tape. For example, the redistribution layers 41 and 43″ may be formed using an ink jet technique.

The redistribution layers 43″ may be formed at the sides and above the embedded interposer 10. The solder paste of the redistribution layers that is located between the semiconductor chip 51 and the embedded interposer 10 may also benefit from the CTE matching between the chip and the interposer. Thus, the strength and durability of the solder paste and other metal interconnects such as redistribution layers 41 and 43″ and package terminals 53 may also be improved as a result of the placement of these layers between the semiconductor chip 51 and the embedded interposer 10.

Referring to FIG. 12, a PSR layer 47′ may be formed to cover the embedded interposer 10, the redistribution layers 41 and 43″ and the base substrate 21. The base substrate 21, the embedded interposer 10, the redistribution layers 41 and 43″, and the PSR layer 47′ may configure a PCB 320′. The PSR layer 47′ may be formed to have openings 49 which expose the external connection terminals 41. The PSR layer 47′ may be formed of an insulating material layer. The PSR layer 47′ may have a step height. Thus, the embedded interposer 10 may be embedded within the PSR layer 47′ and beneath a WL CSP 54 as illustrated in FIG. 13.

Referring to FIG. 13, the WL CSP 54 may be mounted on the PCB 320′.

The WL CSP 54 may be formed to have a semiconductor chip 51, a wafer redistribution layer 52, and package terminals 53. The WL CSP 54 may be attached to the embedded interposer 10 using a conductive adhesive agent 55. The conductive adhesive agent 55 may be disposed between the package terminals 53 and the external connection terminals 41. The conductive adhesive agent 55 may serve to mechanically/electrically connect the semiconductor chip 51 to the PCB 320′ and the mechanical and electrical properties of the conductive adhesive agent 55 may be improved by the placement of the conductive adhesive agent 55 between the embedded interposer 10 and the semiconductor chip 51, both having substantially the same CTE.

As yet another example embodiment, the WL CSP 54 may be replaced with a different semiconductor package such as a flip chip package and an MCP.

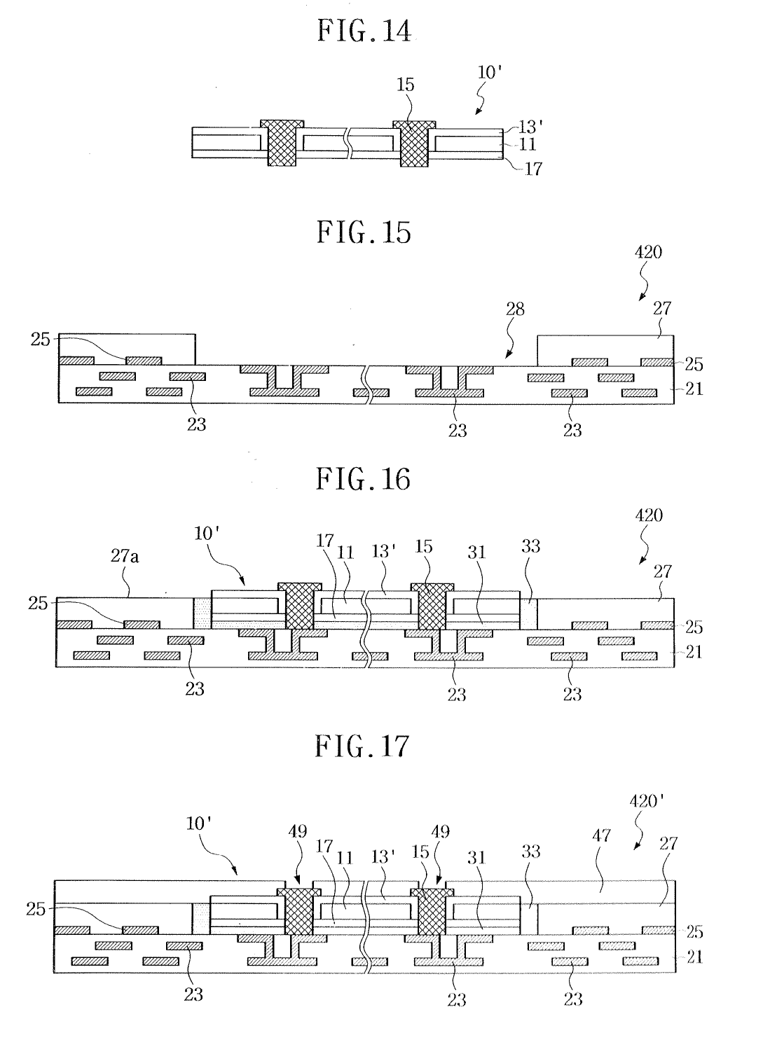

FIGS. 14 to 18 are cross-sectional views illustrating a method of manufacturing a semiconductor device according to still another example embodiment.

Referring to FIG. 14, an embedded interposer 10′ which includes an interposer substrate 11, a first insulating layer 13′, a second insulating layer 17, and first through silicon vias (TSVs) 15 may be formed. The first TSVs 15 may be formed to penetrate and/or extend through the interposer substrate 11. The first insulating layer 13′ may be formed to cover one surface of the interposer substrate 11. The second insulating layer 17 may be formed to cover another surface of the interposer substrate 11. Sidewalls of the first TSVs 15 may be covered with the first insulating layer 13′. The first TSVs 15 may thus be insulated from the interposer substrate 11 by the first insulating layer 13′ and the second insulating layer 17.

The first TSVs 15 may be formed of a conductive layer which is made of Cu, W, WN, Ti, TiN, Ta, TaN, Au, Ag, Ni, Pt, or a combination thereof. The second insulating layer 17 may be formed of an insulating layer such as a silicon oxide layer, a silicon nitride layer, a silicon oxynitride layer, or a combination thereof. The second insulating layer 17 may be formed using a CVD technique or a spin coating technique.

Referring to FIG. 15, a preliminary PCB 420 may be formed by stacking a lamination layer 27 on a base substrate 21. The preliminary PCB 420 may be formed to have a cavity 28 defined by the lamination layer 27. A multi-layer PCB which includes first interconnections 23 and second interconnections 25 may be formed as the base substrate 21. Some of the first interconnections 23 may be exposed by the cavity 28.

Referring to FIG. 16, the embedded interposer 10′ may be attached to a portion of the base substrate 21 which is exposed by the cavity 28 using an adhesive agent 31. The first TSVs 15 may penetrate the adhesive agent 31 to contact the first interconnections 23. A spacer 33 may be formed between the lamination layer 27 and the embedded interposer 10′. When the lamination layer 27 is formed to cover the base substrate 21, the combined structure contributes to form a PCB in which an interposer 10′ may be embedded in the cavity 28. Also, and as further illustrated in FIG. 17, the embedded interposer 10′ may be partially embedded in the base substrate 21 and partially embedded in the lamination layer 27, with a portion of the embedded interposer 10′ being disposed or overlapped above a top surface 27a of the lamination layer 27.

Referring to FIG. 17, a PSR layer 47 may be formed on the lamination layer 27 and the embedded interposer 10′. The base substrate 21, the lamination layer 27, the embedded interposer 10′, and the PSR layer 47 may configure a PCB 420′. The PSR layer 47 may be formed to cover the lamination layer 27 and the embedded interposer 10′. The PSR layer 47 may be formed to have openings 49 which expose one end of each of the first TSVs 15.

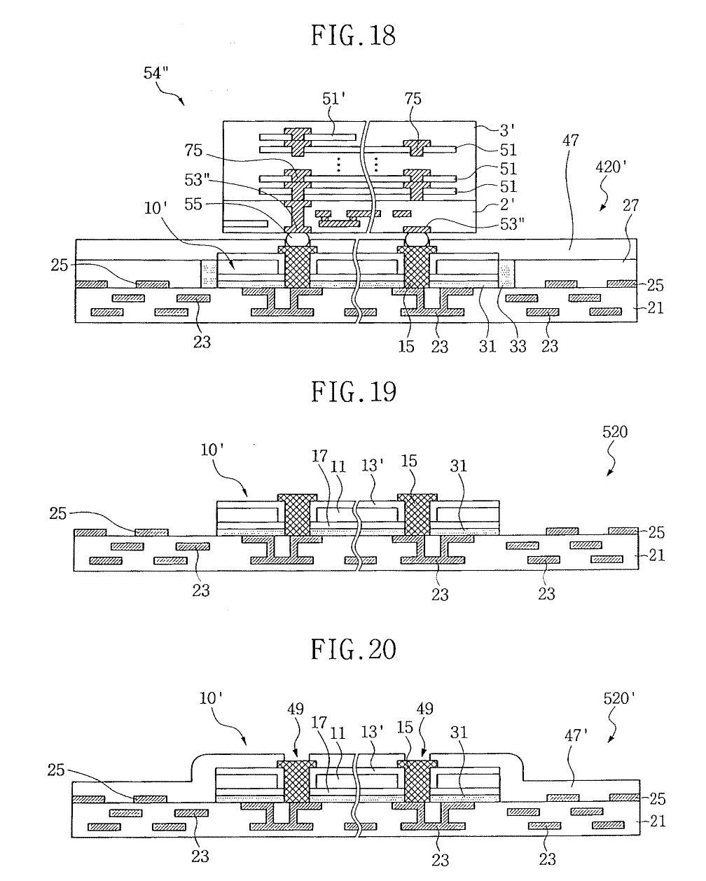

Referring to FIG. 18, an MCP 54″ may be mounted on the PCB 420′.

The MCP 54″ may be formed to have a plurality of semiconductor chips 51 and 51′, a package substrate 2′, an encapsulation material 3′, and package terminals 53″. The semiconductor chips 51 and 51′ may include sequentially stacked memory chips 51 and a control chip 51′. The semiconductor chips 51 and 51′ may be electrically connected to the page terminals 53″ by second TSVs 75. The encapsulation material 3′ may cover the semiconductor chips 51 and 51′ and the package substrate 2′. The embedded interposer 10′ may be formed to have substantially the same CTE as the semiconductor chips 51 and 51′.

The MCP 54″ may be attached to the embedded interposer 10′ using a solder joint such as a conductive adhesive agent 55. The conductive adhesive agent 55 may be disposed between the package terminals 53″ and the first TSVs 15. The conductive adhesive agent may be one selected from the group consisting of a solder ball, a solder paste, a conductive bump, an anisotropic conductive film (ACF), and an anisotropic conductive paste (ACP). The conductive adhesive agent 55 may serve to mechanically/electrically connect the semiconductor chip 51 to the PCB 420′. The strength and durability of not only the conductive adhesive agent 55, but the first and second TSVs 15 and 75 and other metal interconnects such as the package terminals 53″ may also be improved as a result of the placement of these metal interconnect layers between the semiconductor chips 51 and 51′ and the embedded interposer 10.

As yet another example embodiment, the MCP 54″ may be replaced with a different semiconductor package such as a WL CSP and a flip chip package.

FIGS. 19 to 21 are cross-sectional views illustrating a method of manufacturing a semiconductor device according to another example embodiment.

Referring to FIG. 19, an embedded interposer 10′ may be attached to a base substrate 21 using an adhesive agent 31.

The embedded interposer 10′ may include an interposer substrate 11, a first insulating layer 13′, a second insulating layer 17, and first TSVs 15. A multi-layer PCB which includes first interconnections 23 and second interconnections 25 may be formed as the base substrate 21. The base substrate 21 may configure a preliminary PCB 520. The first TSVs 15 may contact the first interconnections 23 through the adhesive agent 31.

Referring to FIG. 20, a PSR layer 47′ may be formed on the base substrate 21 and the embedded interposer 10′. The base substrate 21, the embedded interposer 10′ and the PSR layer 47′ may configure a PCB 520′. The PSR layer 47′ may be formed to cover the base substrate 21 and the embedded interposer 10′. The PSR layer 47′ may be formed to have openings 49 which expose one end of each of the first TSVs 15.

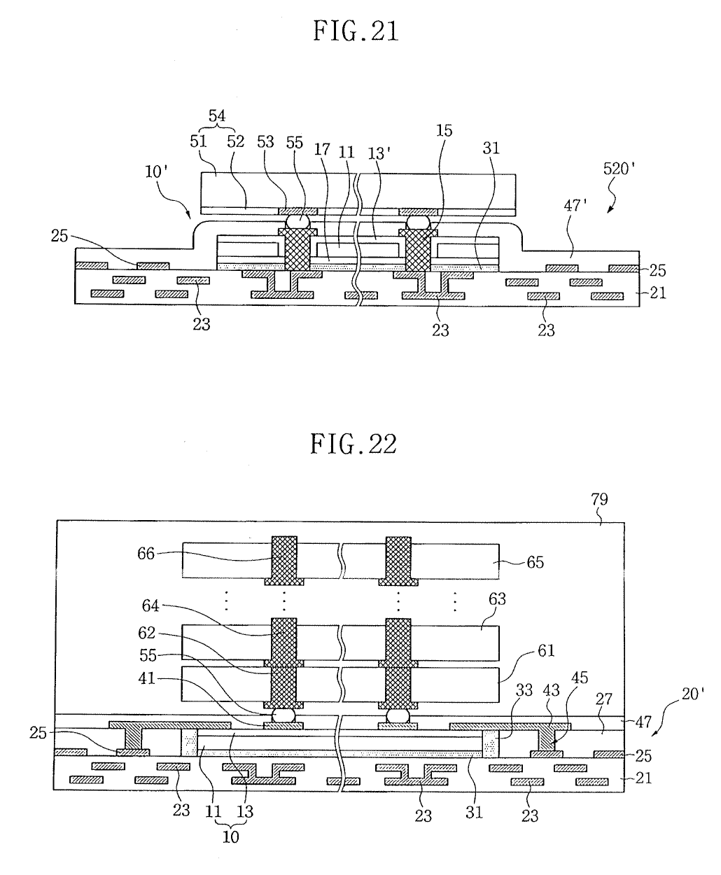

Referring to FIG. 21, a WL CSP 54 may be mounted on the PCB 520′. The WL CSP 54 may be formed to have a semiconductor chip 51, a wafer redistribution layer 52, and package terminals 53.

The WL CSP 54 may be attached to the embedded interposer 10′ using a solder joint such as a conductive adhesive agent 55. The conductive adhesive agent 55 may be disposed between the package terminals 53 and the first TSVs 15. The conductive adhesive agent 55 may serve to mechanically/electrically connect the semiconductor chip 51 to the PCB 520′. The embedded interposer 10′ may be formed to have substantially the same CTE as the semiconductor chip 51. Therefore, the strength and durability of the solder joint not only including the conductive adhesive agent 55, but the TSV 15 and package terminals 53 may also be improved as a result of the placement of these metal interconnect layers between the semiconductor chips 51 and the embedded interposer 10′.

As yet another example embodiment, the WL CSP 54 may be replaced with a different package such as a flip chip package and an MCP.

FIG. 22 is a cross-sectional view illustrating a method of manufacturing a semiconductor device according to another example embodiment.

Referring to FIG. 22, semiconductor chips 61, 63 and 65 may be mounted on a PCB 20′ having an embedded interposer 10. The PCB 20′ may have a similar configuration to the first example embodiment described with reference to FIGS. 1 to 4.

A first semiconductor chip 61 may be mounted on the PCB 20′. The first semiconductor chip 61 may be formed to have first TSVs 62. The first semiconductor chip 61 may be formed using a semiconductor wafer such as a silicon wafer. The first TSVs 62 may be formed of a conductive layer which is made of Cu, W, WN, Ti, TiN, Ta, TaN, Au, Ag, Ni, Pt, or a combination thereof.

The first semiconductor chip 61 may be attached to the embedded interposer 10 using a solder joint such as a conductive adhesive agent 55. The conductive adhesive agent 55 may be disposed between the first TSVs 62 and external connection terminals 41. The conductive adhesive agent 55 may be one selected from the group consisting of a solder ball, a solder paste, a conductive bump, an anisotropic conductive film (ACF), and an anisotropic conductive paste (ACP). The conductive adhesive agent 55 may serve to mechanically/electrically connect the first semiconductor chip 61 to the PCB 20′.

The embedded interposer 10 may be formed to have substantially the same CTE as the semiconductor chips 61, 63 and 65. Therefore, the strength and durability of the solder joint not only including the conductive adhesive agent 55, but the TSVs 62, 64 and 66 and distribution layers 41 and 43 may also be improved as a result of the placement of these metal interconnect layers between the semiconductor chips 51 and the embedded interposer 10′.

The embedded interposer 10 may be formed to have substantially the same CTE as the first semiconductor chip 61. For example, the interposer substrate 11 and the first semiconductor chip 61 may be formed using a semiconductor wafer. Accordingly, mechanical/electrical characteristics of the conductive adhesive agent 55 may be significantly improved compared to the conventional art.

A second semiconductor chip 63 having second TSVs 64 may be stacked on the first semiconductor chip 61. The second semiconductor chip 63 may be electrically connected to the first semiconductor chip 61 and the PCB 20′ through the first TSVs 62 and the second TSVs 64. A third semiconductor chip 65 having third TSVs 66 may be stacked on the second semiconductor chip 63. The third semiconductor chip 65 may be electrically connected to the PCB 20′ through the first to third TSVs 62, 64 and 66. A plurality of different semiconductor chips may be stacked between the third semiconductor chip 65 and the second semiconductor chip 63. An encapsulation material 79 may be formed to cover the entire surface of the PCB 20′ using a molding compound, a metal cap or a ceramic cap. The semiconductor chips 61, 63 and 65 may be covered with the encapsulation material 79.

The semiconductor chips 61, 63 and 65 may include a volatile memory device such as a DRAM, a non-volatile memory device such as a flash memory, a microprocessor, a logic device, or a combination thereof.

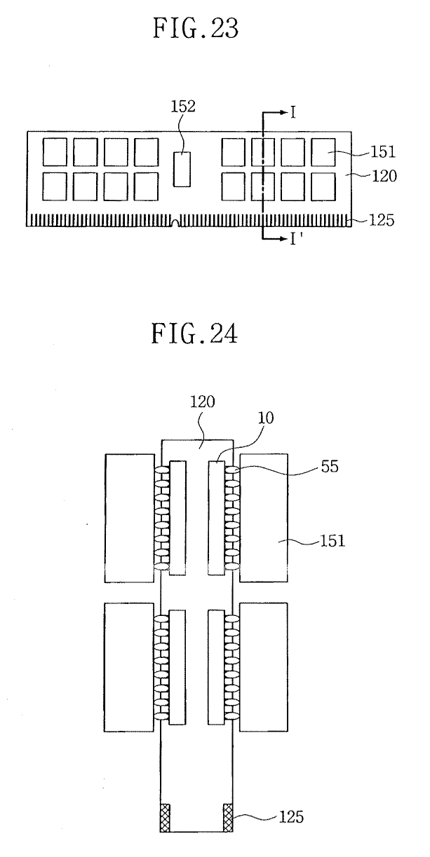

FIG. 23 is a plan view illustrating a method of manufacturing a semiconductor device according to still another example embodiment, and FIG. 24 is a cross-sectional view taken along line I-I′ of FIG. 23.

Referring to FIGS. 23 and 24, semiconductor packages 151 may be mounted onto a PCB 120 having an embedded interposer 10 using a solder joint such as a conductive adhesive agent 55. The embedded interposer 10 may be formed to have substantially the same CTE as the semiconductor packages 151. The PCB 120 may have a similar configuration to those described with reference to FIGS. 1 to 22. The conductive adhesive agent 55 may be disposed between the semiconductor packages 151 and the embedded interposer 10. A plurality of tabs 125 may be formed on one end of the PCB 120. Different semiconductor devices such as a register chip 152 and/or a logic chip (not illustrated) may be mounted on one surface of the PCB 120 but for simplicity are not illustrated in the drawing. The tabs 125 may be electrically connected to the register chip 152 and the semiconductor packages 151 in series or parallel.

The semiconductor device according to the present example embodiment may be a semiconductor module. The semiconductor packages 151 may be selected from the group consisting of WL CSPs, flip chip packages and MCPs. The semiconductor packages 151 may include a volatile memory device such as a DRAM, a non-volatile memory device such as a flash memory, a microprocessor, a logic device, or a combination thereof. For example, the semiconductor packages 151 may include a volatile memory device such as a DRAM. In this case, the semiconductor device according to the present example embodiment may be a memory module.

Alternatively, the semiconductor packages 151 may be replaced with semiconductor chips. The semiconductor chips can include a volatile memory device such as a DRAM, a non-volatile memory device such as a flash memory, a microprocessor, a logic device, or a combination thereof.

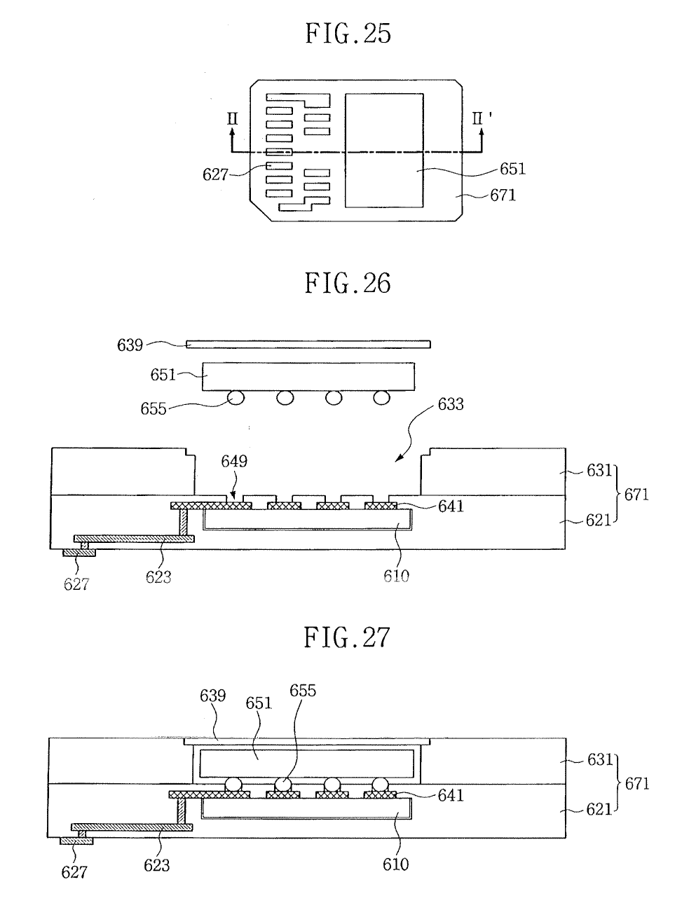

FIG. 25 is a plan view illustrating a method of manufacturing a semiconductor device according to another example embodiment, FIG. 26 is an exploded cross-sectional view taken along line II-II′ of FIG. 25, and FIG. 27 is a cross-sectional view taken along line II-II′ of FIG. 25.

Referring to FIGS. 25, 26 and 27, a semiconductor package 651 may be mounted onto a card substrate 671 which includes a PCB 621 and a housing 631 using a solder joint such as a conductive adhesive agent 655.

The PCB 621 may have a similar configuration to those described with reference to FIGS. 1 to 22 and include an embedded interposer 610 embedded in the PCB 621 and external connection terminals 641. The external connection terminals 641 may be electrically connected to card terminals 627 formed on one surface of the PCB 621 via inner interconnections 623. The housing 631 may cover the PCB 621. The housing 631 may include a cavity 633 formed on the embedded interposer 610. Openings 649 may be formed on the external connection terminals 641. The external connection terminals 641 may be exposed in the cavity 633. The housing 631 may be formed of an encapsulation material such as a molding compound, a metal cap or a ceramic cap.

The conductive adhesive agent 655 may be disposed between the semiconductor package 651 and the external connection terminals 641. The conductive adhesive agent 655 may be one selected from the group consisting of a solder ball, a solder paste, a conductive bump, an anisotropic conductive film (ACF), and an anisotropic conductive paste (ACP). The conductive adhesive agent 655 may serve to mechanically/electrically connect the semiconductor chip 651 to the PCB 621. A cap 639 may be formed to cover the semiconductor package 651. The cap 639 may be formed of an encapsulation material such as a molding compound, a metal cap or a ceramic cap. The cap 639 may be formed to be planar with an upper surface of the housing 631. The planar surface may be achieved by various deposition techniques as are known in the art or by deposition and subsequent polishing.

The embedded interposer 610 may be formed to have substantially the same CTE as the semiconductor package 651. Therefore, the strength and durability of not only including of not only the conductive adhesive agent 55, but the external connection terminals 641 may also be improved as a result of the placement of these metal interconnect layers between the semiconductor package 651 and the embedded interposer 610.

The semiconductor device according to the present example embodiment may be a semiconductor card package. The semiconductor package 651 may be one selected from the group consisting of a WL CSP, a flip chip package and an MCP. The semiconductor packages 651 may include one selected from the group consisting of a volatile memory device such as a DRAM, a non-volatile memory device such as a flash memory, a microprocessor, a logic device, or a combination thereof. For example, the semiconductor package 651 may include a non-volatile memory device such as a flash memory. In this case, the semiconductor device according to the present example embodiment may be a memory card.

Alternatively, the semiconductor package 651 may be replaced with a semiconductor chip. The semiconductor chip may include a volatile memory device such as a DRAM, a non-volatile memory device such as a flash memory, a microprocessor, a logic device, or a combination thereof.

### Experimental Example

TABLE 1
Solder joint reliability of a semiconductor
device having an embedded interposer

| | Semiconductor | Embedded | | SJR |
|---|---|---|---|---|
| Case | chip (mm) | interposer (mm) | Cycle | Improvement |
| case 1 | 9.1 × 13.84 × 0.55 | — | 822 | 1.0 |
| case 2 | | 8.8 × 12.8 × 0.1 | 995 | 1.2 |
| case 3 | | 9.1 × 13.84 × 0.1 | 1000 | 1.21 |
| case 4 | | 10.16 × 16.76 × 0.1 | 1020 | 1.24 |
| case 5 | | 9.1 × 13.84 × 0.2 | 1153 | 1.4 |
| case 6 | | 9.1 × 13.84 × 0.3 | 1276 | 1.55 |

Table 1 shows solder joint reliability simulation results for a semiconductor device having an embedded interposer according to example embodiments. In the present experimental example, a semiconductor device having a similar configuration to the first example embodiment illustrated in FIG. 5, for example, was used in the simulation. As recorded in Table 1, the WL CSP with semiconductor chips of the same size was used, the embedded interposers had different sizes including different lengths, widths and depts, and a solder ball was used as the conductive adhesive agent. A temperature cycle (T/C) test which is used for a semiconductor reliability test was used in the solder joint reliability simulation of Table 1. In Table 1, a cycle denotes the number of times that temperature stress is applied until a crack occurs in the solder ball.

In Table 1, the column labeled SJR Improvement measures the reliability of five different configurations of solder joints from Case 2 to Case 6. These cases use embedded interposers and are compared to a solder joint Case 1 which does not use an embedded interposer. Other columns include Semiconductor Chip (mm) which illustrates that the same size chip was used for all of the testing, and Embedded Interposer (mm) which illustrates the different dimensions of the embedded interposer which was used in the simulation.

Referring to Table 1, when the embedded interposer was not used, as in case 1, a solder joint crack occurred after 822 cycles. To obtain a starting ratio, the value of 822 cycles is divided by 822 to arrive at the starting value of 1.0 for case 1. When the embedded interposers of different sizes were used, as in cases 2 to 6, a solder joint crack occurred between 995 and 1276 cycles, depending on different factors such as the dimensions of the embedded interposer. Using different dimensions of the embedded interposer listed in Table 1, the number of cycles increases from case 2 to case 6 and is recorded in the table. To calculate the SJR improvement, in cases 2 to 6, the number of cycles is divided by 822 to arrive at an improvement ratio. Thus, in case 2, 995 cycles is divided by 822 cycles to arrive at an SJR improvement ratio of 1.2 In case 3, 1000 cycles is divided by 822 cycles to arrive at an SJR improvement ratio of 1.21, and so on. The data shows among other things that the larger the dimensions of the embedded interposer, as well as the larger the thickness, or depth of the interposer, the SJR improvement increases. Accordingly, as recorded in Table 1, solder joint reliability (SJR) was improved by 1.2 to 1.55 times better than the conventional art of case 1 that does not use an embedded interposer when the embedded interposer was used.

Using an embedded interposer and semiconductor chips having substantially the same CTE as described in the exemplary embodiments of the present general inventive concept may decrease the breakdown ability of the conductive adhesive and other metal interconnect layers and vias, thus providing for a longer life of the semiconductor package as a whole. By using the embedded interposer 10 of the present general inventive concept, the electrical resistance of the conductive adhesive may be reduced, cracking of solder joints may be inhibited, and mechanical bond strength between the semiconductor substrate and the PCB may be increased.

Example embodiments provide a PCB having an embedded interposer and a semiconductor chip or a semiconductor package mounted onto the embedded interposer using a conductive adhesive agent. The embedded interposer has substantially the same CTE as the semiconductor chip. Accordingly, mechanical/electrical characteristics such as solder joint reliability (SJR) of the conductive adhesive agent are significantly improved compared to the conventional art.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages. Accordingly, all such modifications are intended to be included within the scope of this present general inventive concept as defined in the claims. In the claims, means-plus-function clauses are intended to cover the structures described herein as performing the recited function, and not only structural equivalents but also equivalent structures. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

Although a few embodiments of the present general inventive concept have been illustrated and described, it will be appreciated by those skilled in the art that changes may be made in these embodiments without departing from the principles and spirit of the general inventive concept, the scope of which is defined in the appended claims and their equivalents.

1. A method of manufacturing a semiconductor device, comprising:
forming a printed circuit board (PCB) having an embedded interposer; and
mounting a semiconductor chip or a semiconductor package onto the embedded interposer using a conductive adhesive agent,
wherein the embedded interposer has substantially the same coefficient of thermal expansion (CTE) as the semiconductor chip.

2. The method of claim 1, wherein the embedded interposer is formed using a semiconductor wafer.

3. The method of claim 1, wherein forming the PCB comprises:
preparing a base substrate; and
attaching the embedded interposer to the base substrate.

4. The method of claim 3, further comprising forming a lamination layer which covers the base substrate,
wherein the lamination layer has a cavity which partially exposes the base substrate, and the embedded interposer is disposed in the cavity.

5. The method of claim 3, further comprising forming a cavity in the base substrate,
wherein the embedded interposer is disposed in the cavity.

6. The method of claim 3, further comprising forming a redistribution layer which electrically connects the embedded interposer to the base substrate.

7. The method of claim 6, wherein the redistribution layer is formed using an ink jet technique.

8. The method of claim 3, further comprising forming a through silicon via (TSV) which penetrates the embedded interposer.

9. The method of claim 3, further comprising forming a photo solder resist (PSR) layer which covers the embedded interposer.

10. The method of claim 1, wherein the conductive adhesive agent is a solder joint that comprises one selected from the group consisting of a solder ball, a solder paste, a conductive bump, an anisotropic conductive film (ACF), and an anisotropic conductive paste (ACP).

11. The method of claim 1, wherein the semiconductor package comprises one selected from the group consisting of a wafer level chip scale package (WL CSP), a flip chip package, and a multi-chip package (MCP).

12. A method of manufacturing a semiconductor module, comprising:
forming a printed circuit board (PCB) which includes an embedded interposer and a plurality of tabs; and
mounting a semiconductor chip or a semiconductor package onto the embedded interposer using a conductive adhesive agent,
wherein the embedded interposer has substantially the same coefficient of thermal expansion (CTE) as the semiconductor chip, and the tabs are electrically connected to the semiconductor chip or the semiconductor package.

13. The method of claim 12, wherein the embedded interposer is formed using a semiconductor wafer.

14. The method of claim 12, wherein the conductive adhesive agent comprises one selected from the group consisting of a solder ball, a solder paste, a conductive bump, an anisotropic conductive film (ACF), and an anisotropic conductive paste (ACP).

15. The method of claim 12, wherein the semiconductor package comprises one selected from the group consisting of a wafer level chip scale package (WL CSP), a flip chip package, and a multi-chip package (MCP).

16. The method of claim 15, wherein the semiconductor package comprises a dynamic random access memory (DRAM).

17. A method of manufacturing a semiconductor card package, comprising:
forming a printed circuit board (PCB) which includes an embedded interposer and card terminals; and
mounting a semiconductor chip or a semiconductor package onto the embedded interposer using a conductive adhesive agent,
wherein the embedded interposer has substantially the same coefficient of thermal expansion (CTE) as the semiconductor chip, and the card terminals are electrically connected to the semiconductor chip or the semiconductor package.

18. The method of claim 17, wherein the embedded interposer is formed using a semiconductor wafer.

19. The method of claim 17, wherein the semiconductor package comprises one selected from the group consisting of a wafer level chip scale package (WL CSP), a flip chip package, and a multi-chip package (MCP).

20. The method of claim 19, wherein the semiconductor package comprises a non-volatile memory device.

21-24. (canceled)

25. A method of forming a semiconductor package, the method comprising:
forming a semiconductor substrate having a plurality of first interconnects therein and a plurality of second interconnects disposed above the semiconductor substrate;
forming a lamination layer above the semiconductor substrate and above the plurality of second interconnects, the lamination layer being formed with a cavity therein;
embedding an interposer having a coefficient of thermal expansion (CTE) in the cavity of the lamination layer through an adhesive agent;
forming through silicon vias (TSVs) in the embedded interposer to contact the first interconnects;
forming at least one conductive adhesive agent and a plurality of metal interconnects above the TSVs;
forming a plurality of semiconductor chips above the plurality of metal interconnects, wherein the plurality of semiconductor chips have substantially the same CTE as the embedded interposer.

26. The method of claim 25, further comprising:
forming a packaging substrate between the at least one conductive adhesive agent and below the plurality of semiconductor chips.
